(19) United States
(12) Patent Application Publication
(10) Pub. No.: US 2024/0360048 A1
(43) Pub. Date: Oct. 31, 2024

(54) EXTERNAL PART MADE OF CERAMIC MATERIAL COMPRISING A PROTECTIVE LAYER AND METHOD FOR PRODUCING SUCH AN EXTERNAL PART

(71) Applicant: The Swatch Group Research and Development Ltd, Marin (CH)

(72) Inventors: Loïc CURCHOD, Lausanne (CH); Vladislav SPASSOV, Praz (CH); Lucie TABARD, Neuchatel (CH); Marta FORNABAIO, Crissier (CH)

(73) Assignee: The Swatch Group Research and Development Ltd, Marin (CH)

(21) Appl. No.: 18/611,800

(22) Filed: Mar. 21, 2024

(30) Foreign Application Priority Data
Apr. 28, 2023 (EP) 23170798.5

(51) Int. Cl. C04B 41/87; C04B 41/00; C04B 41/45; C04B 41/50; C23C 14/06; C23C 14/08; C23C 14/34

(52) U.S. Cl. CPC C04B 41/87; C04B 41/009; C04B 41/4515; C04B 41/5032; C04B 41/5067; C23C 14/0676; C23C 14/08; C23C 14/34

(57) ABSTRACT

An external part including a substrate made of ceramic material on a surface of which extends a transparent inorganic protective coating, the protective coating being configured so as to have a refractive index substantially equal to that of the substrate in the visible range of the light spectrum, so that the external part has a colour substantially identical to the intrinsic colour of the substrate, the coating extending over a thickness chosen between 300 nm and 5 μm.

### TECHNICAL FIELD OF THE INVENTION

The invention relates to decorative articles in the fields of watchmaking, jewellery or fashion articles, and more particularly relates to an external part made of ceramic material comprising a protective coating and a method for producing such an external part.

In this text, the terms “external part” are commonly used in the above-mentioned fields to designate a part that is visible to a user and has a decorative function in particular.

Fashion articles moreover comprise articles or accessories for clothing, such as belts, shoes, garments, etc., and further comprise writing instruments, eyewear, leather goods, telephones or any decorative articles.

### TECHNOLOGICAL BACKGROUND

In the watchmaking field, a number of solutions have been developed to protect ceramic external parts such as dials, flanges, bezels, middle parts, crowns, push-pieces, links, etc. from chemical and/or mechanical attack that can alter their appearance or colour.

By way of example, the external parts may include a thin protective layer deposited by a vacuum deposition method, such as PVD (Physical Vapour Deposition), CVD (Chemical Vapour Deposition) or ALD (Atomic Layer Deposition) deposition method.

However, no solution in the prior art is entirely satisfactory. Indeed, no protective layer in the prior art has a small thickness, for example less than 5 μm, while being perfectly transparent, that is to say not absorbing, in the visible range of the light spectrum, a portion of the incident light radiation, not giving interferential colours and having appropriate resistance to chemical and mechanical attack.

It should be noted that thin layers deposited by ALD deposition methods have advantages over thin layers deposited by PVD and CVD deposition methods. Indeed, these ALD thin layers are very effective in protecting the substrate from chemical attack, and due to their small thickness, they are invisible to the naked eye so that they do not affect the visual appearance of the substrate they cover.

However, because they are very thin, these layers are very sensitive to mechanical stresses, such as friction or impact. They cannot therefore be used to cover external parts likely to come into contact with external elements, such as the bezel or middle part of a watch.

Layers having a thickness greater than that of ALD thin layers, typically in the micron range, offer greater resistance to mechanical stress. However, these layers are visible on the substrate and therefore do not meet the requirements if the visual appearance of the substrate is to be preserved, particularly for decorative reasons.

There is therefore a need for a protection solution that is effective against chemical and mechanical attacks, and that is suitable for preserving the visual appearance of the substrate thus protected.

### SUMMARY OF THE INVENTION

The invention overcomes the aforementioned disadvantages and, to this end, relates to an external part, preferably for a watch, comprising a substrate made of ceramic material on a surface of which extends a transparent inorganic protective coating. The coating is configured so as to have a refractive index, at least at the interface with the substrate, substantially equal to that of the substrate for wavelengths in the visible range of the light spectrum, so that it generates no interference phenomena, or very few, that is to say substantially not visible to the naked eye, and so that the external part has a colour substantially identical to the intrinsic colour of the substrate.

The coating also has a thickness which is relatively small, which saves deposition time and production costs for the external part, while being sufficiently high to give it good mechanical resistance to abrasion and good protection against chemical attack. In particular, the thickness of the coating is comprised between 300 nm and 5 μm. The coating can advantageously have a high hardness, typically a Vickers hardness of the order of 25 GPa.

The invention thus allows to protect the external part while allowing it to retain the intrinsic colour of the substrate.

In particular embodiments, the invention may further include one or more of the following features, taken alone or in any technically possible combination.

In particular embodiments, the protective coating is configured so that it imparts to the external part a colour whose difference from the intrinsic colour of the substrate is characterised by Delta E≤10 in the L*a*b* colour space.

In particular embodiments, the protective coating is configured so that it imparts to the external part a colour whose difference from the intrinsic colour of the substrate is characterised by Delta E≤5 in the L*a*b* colour space.

In particular embodiments, the thickness of the protective coating is comprised between 300 nm and 1 μm.

In particular embodiments, the protective coating is formed of at least two compounds having respectively, for wavelengths in the visible range of the light spectrum, a refractive index greater than that of the substrate and a refractive index less than that of the substrate. By controlling the proportion of each compound in the composition of the protective coating, the refractive index of the protective coating can be finely controlled so that it is substantially equal to the refractive index of the substrate, thereby eliminating any interference phenomena.

In particular embodiments, the protective coating includes at least one layer made of TiₓAl_{y}O_{z}.

In particular embodiments, the protective coating includes at least one layer made of SiₓO_{y}N_{z}.

In particular embodiments, the substrate can be made of oxide, nitride, carbide, carbonitride or boride, in particular alumina Al₂O₃, zirconia ZrO₂ or an alumina-zirconia composite.

According to another aspect, the present invention further relates to a method for manufacturing an external part for example as described above, comprising the steps of preparing a surface of a substrate, and depositing a transparent inorganic protective coating on said surface by a vacuum deposition method, in a reactive or non-reactive atmosphere.

The deposition step is carried out from at least one source of at least one material chosen so that the protective coating has a refractive index substantially equal to that of the substrate in the visible range of the light spectrum, said step also being carried out so that the protective coating has a thickness comprised between 300 nm and 5 μm, so that it is resistant to mechanical and chemical attack.

In particular implementations, the step of depositing a protective coating is carried out by cathodic sputtering method.

In particular implementations, the protective coating is deposited from at least two sources of different materials, said materials being chosen so that, during the deposition step, they each form a compound having, in the visible range of the light spectrum, respectively a refractive index greater than that of the substrate and a refractive index less than that of the substrate. The sputtering power of each of the sources is controlled so that the proportions of each compound in the protective coating are such that said coating has a refractive index substantially identical to that of the substrate.

In particular implementations, the protective coating is deposited from at least one source of a mixture of at least two materials, said materials being chosen so that, during the deposition step, they each form a compound having, in the visible range of the light spectrum, respectively a refractive index greater than that of the substrate and a refractive index less than that of the substrate. The source is prepared so as to include predefined proportions of said materials so that the protective coating has, at the end of the deposition step, a refractive index substantially identical to that of the substrate.

In particular implementations, the materials chosen are Al and Ti, the deposition step being carried out using O₂ as the reactive gas so that, at the end of the deposition step, the protective coating comprises a mixture of TiO₂ and Al₂O₃ so as to form a compound of the type TiₓAl_{y}O_{z}.

In particular implementations, the protective coating is deposited from at least one source of a single material chosen so that, during the deposition step, it forms several compounds by reacting with several reactive gases present. In the visible range of the light spectrum, the compounds respectively have a refractive index greater than that of the substrate and a refractive index less than that of the substrate, the reactive gases being present in predefined proportions so that, at the end of the deposition step, the protective coating has a refractive index substantially identical to that of the substrate.

In particular implementations, the deposition step is carried out from a source made of Si and using O₂ and N₂ as reactive gases so that, at the end of the deposition step, the protective coating comprises a mixture of SiO₂ and Si₃N₄ so as to form a compound of the type SiₓO_{y}N_{z}.

### BRIEF DESCRIPTION OF THE FIGURES

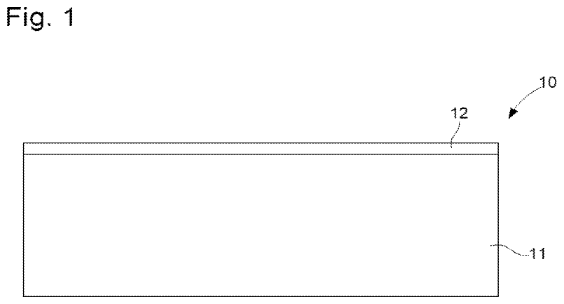

Other features and advantages of the invention will become apparent from the following detailed description, which is given as a non-limiting example, with reference to FIG. 1, which schematically shows a cross-sectional view of an external part according to a preferred embodiment of the invention.

Note that the FIGURE is not necessarily drawn to scale for reasons of clarity.

### DETAILED DESCRIPTION OF THE INVENTION

The invention relates to an external part 10, as shown schematically in FIG. 1. The external part 10 according to the invention is suitable for the fields of watchmaking, jewellery, fashion articles, etc. Preferably, the external part 10 is intended to form a watch dial, a middle part, a bezel, a bracelet or any other watch component visible to a user.

The external part 10 comprises a dielectric substrate 11, for example made of a ceramic material, such as alumina Al₂O₃ or zirconia ZrO₂ or an alumina-zirconia composite, with or without pigments colouring said substrate. The external part 10 further includes a transparent inorganic protective coating 12 extending over a surface of the substrate 11 intended to be visible to a user.

It should be noted that the term “transparent” in this text refers to the ability of a material not to absorb light visibly to the human eye.

The protective coating 12 can be formed by a single thin layer or by several thin layers.

Advantageously, the protective coating 12 allows to protect the substrate 11 against chemical attacks, in particular generated by humidity, sulphurous gases, oxygen and acidic environments. Furthermore, the protective coating 12 is dimensioned so as to resist mechanical stresses, in particular those generated by friction or impact.

To this end, the protective coating 12 extends over a thickness chosen, for example, between 300 nm and 5 μm, more particularly between 300 nm and 1 μm. Preferably, the thickness of the protective coating 12 is equal to 1 μm.

The protective coating 12 is configured to have a refractive index substantially equal to that of the substrate 11 in the visible range of the light spectrum, at least at the interface with said substrate 11. In this text, the refractive index of the protective coating 12 is substantially equal to that of the substrate 11 to the extent that it is comprised within an interval of plus or minus five percent of the value of the substrate 11.

Advantageously, these features allow the protective coating 12 to produce little or no optical interference, and therefore allow the external part 10 protected by the layer 12 to have the intrinsic colour of the substrate 11. It should be noted that any interference produced is so slight that it is not visible to a user and is therefore negligible.

The notion of “intrinsic colour” refers, in the present text, to the colour of the uncoated substrate 11 as perceived by a user when illuminated by white light, due to the material(s) of which it is composed. Thus, the protective coating 12 is not visible to the naked eye in the sense that the external part 10 has substantially the same colour with or without the protective coating 12 deposited on the substrate 11.

More specifically, the protective coating 12 is configured so that it imparts to the external part 10 a colour whose difference from the intrinsic colour of the substrate 11 is characterised by Delta E≤10 in the L*a*b* colour space, and more particularly Delta E≤5.

In summary, thanks to the features of the invention, the external part 10 includes chemical protection for the substrate 11 while maintaining the aesthetic appearance and mechanical strength of the latter.

Preferably, the protective coating is formed of at least two compounds having respectively, for wavelengths in the visible range of the light spectrum, a refractive index higher than that of the substrate 11 and a refractive index lower than that of the substrate 11.

For example, the protective coating 12 may include a mixture of TiO₂, which has a high refractive index, and Al₂O₃, which has a low refractive index. It should be noted that this example of protective coating 12 is not compatible with a substrate 11 made of a material whose refractive index is lower than that of a coating of Al₂O₃ alone or higher than that of a coating of TiO₂ alone.

Alternatively, the protective coating 12 can include a mixture of Si₃Ni₄, which has a high refractive index, and SiO₂, which has a low refractive index.

More generally, to summarise, the protective coating 12 may include at least one thin layer made of TiₓAl_{y}O_{z} or SiₓO_{y}N_{z}.

The present invention also relates to a method for manufacturing an external part 10, for example the external part 10 as previously described. The method comprises the steps of preparing the surface of the substrate 11 intended to be visible to a user, and depositing the protective coating 12 on said surface by a vacuum deposition method.

The preparation step may involve polishing the substrate 11, sandblasting, brushing, satin-finishing or carrying out any other surface preparation operation.

The deposition step is carried out using one or more sources of materials whose composition is chosen so as to form a protective coating 12 having a refractive index substantially equal to that of the substrate 11 in the visible range of the light spectrum.

This deposition step is also carried out in such a way as to deposit the protective coating 12 so that it has a thickness such that it resists mechanical attacks, particularly abrasion, and chemical attacks, as described above.

Moreover, the method may include a preliminary step of preparing at least one material source used during the deposition step. The step of preparing the sources allows, for example, to adapt the appropriate type of source according to the vacuum deposition method used during the deposition step and to adapt the proportion of materials in the source when it includes a plurality of materials in order to obtain the desired protective coating 12. The type of material source varies according to the vacuum deposition method used, in that the source is a target in solid form if the deposition method used is a physical vapour deposition PVD method, and the source is a gas-phase precursor if the deposition method used is a chemical vapour deposition CVD method or an atomic layer deposition ALD method.

In one variant implementation of the method, the protective coating 12 is deposited from at least two sources of different materials, for example different metal materials. Said materials are chosen so that, during the deposition step, they each form a compound, for example an oxide, a nitride or a carbide, said compounds having, in the visible range of the light spectrum, respectively a refractive index greater than that of the substrate 11 and a refractive index less than that of the substrate 11. During the deposition step, by controlling the sputtering power of each of the sources, the proportion of each compound deposited to form the protective coating 12 is controlled so that the latter has the desired refractive index. This desired refractive index of the protective coating 12 is substantially identical to that of the substrate 11, as described above.

For example, one of the materials may be Al and the other may be Ti. The preliminary preparation step is then carried out so as to obtain two sources, one of which is made of Ti and the other of Al, and the deposition step is carried out using O₂ as the reactive gas. In this example, at the end of the deposition step, the protective coating 12 is then formed of a mixture of TiO₂ and Al₂O₃. Since these two metal oxides have a refractive index higher and lower respectively than that of the substrate 11, controlling their proportion in the protective coating 12 allows to control the refractive index of the coating 12.

In another variant implementation of the method, the protective coating 12 is deposited from at least one source of a mixture of at least two materials. Said materials are also chosen so that, during the deposition step, they each form a compound, for example an oxide, a nitride, a boride or a carbide, said compounds having, in the visible range of the light spectrum, respectively a refractive index greater than that of the substrate 11 and a refractive index less than that of the substrate 11. During the preliminary step, the source is prepared so as to include predefined proportions of said materials so as to control the composition of the deposited protective coating 12 so that the latter has the desired refractive index at the end of the deposition step.

For example, it is conceivable that the preliminary preparation step is implemented so as to obtain a source of a mixture of Ti and Al, and that the deposition step is implemented using O₂ as the reactive gas. In this example, at the end of the deposition step, the protective coating 12 is then composed of a mixture of TiO₂ and Al₂O₃. In the same way as in the previous variant implementation, since these two metal oxides respectively have a refractive index higher and lower than that of the substrate 11, controlling their proportion in the protective coating 12 allows to control the refractive index of the coating 12 so that it is substantially equal to that of the substrate 11. As the source is prepared upstream with the predefined proportions of each material, this variant is more suitable for implementing the method industrially, simply, quickly and stably.

In yet another variant implementation of the method, the protective coating 12 can be deposited from at least one source of a single material chosen so that, during the deposition step, depending on the reactive gases used, such as O₂ or N₂, it forms different compounds. In the visible range of the light spectrum, the compounds respectively have a refractive index lower than that of the substrate 11 and a refractive index higher than that of the substrate 11. Thus, by controlling the amount of each gas present during the deposition step, the stoichiometry of the compounds making up the protective coating 12 is controlled so as to obtain the desired refractive index of the protective coating 12.

For example, the preliminary preparation step can be carried out so as to obtain a Si source, and the deposition step can be carried out using N₂ and O₂ as reactive gases. In this example, at the end of the deposition step, the protective coating 12 is composed of a mixture of SiO₂ and Si₃N₄. The mixture between a metal oxide and a nitride of the same metal in controlled proportions therefore allows to control the refractive index of the coating 12 so that it is substantially identical to that of the substrate 11.

These different variant implementations advantageously allow to obtain a protective coating 12 with an effective refractive index corresponding as precisely as possible to that of the substrate 11, with a high degree of adaptability and in a relatively simple way, by adjusting the ratios between the different compounds making up the protective coating 12.

The step of depositing a protective coating 12 is preferably carried out by a physical vapour deposition PVD method, for example by arc evaporation, laser ablation, ion beam sputtering or electron beam or Joule effect evaporation, preferably by cathodic sputtering, in a reactive or non-reactive atmosphere. Alternatively, the deposition step can be carried out by any chemical vapour deposition CVD or atomic layer deposition ALD method.

More generally, it should be noted that the implementations and embodiments considered above have been described by way of non-limiting examples, and that other variants are therefore possible.

In particular, materials other than those mentioned in the variant implementations of the method described above may be used. In particular, the use of sources of metal materials has been described, but it is also possible to use sources of non-metal materials.

1. An external part, comprising a substrate made of ceramic material on a surface of which extends a transparent inorganic protective coating, said protective coating being configured so as to have a refractive index substantially equal to that of the substrate in the visible range of the light spectrum, so that the external part has a colour substantially identical to the intrinsic colour of the substrate, said coating extending over a thickness chosen between 300 nm and 5 μm.

2. The external part according to claim 1, wherein the protective coating is configured to impart to the external part a colour whose difference from the intrinsic colour of the substrate is characterised by Delta E≤10 in the L*a*b* colour space.

3. The external part according to claim 2, wherein the protective coating is configured to impart to the external part a colour whose difference from the intrinsic colour of the substrate is characterised by Delta E≤5 in the L*a*b* colour space.

4. The external part according to claim 1, wherein the thickness of the protective coating is comprised between 300 nm and 1 μm.

5. The external part according to claim 1, wherein the protective coating is formed of at least two compounds having respectively, for wavelengths in the visible range of the light spectrum, a refractive index greater than that of the substrate and a refractive index less than that of the substrate.

6. The external part according to claim 1, wherein the protective coating includes at least one layer made of TiₓAl_{y}O_{z}.

7. The external part according to claim 1, wherein the protective coating includes at least one layer made of SiₓO_{y}N_{z}.

8. The external part according to claim 1, wherein the substrate is made of alumina Al₂O₃, zirconia ZrO₂ or an alumina-zirconia composite.

9. A method for manufacturing an external part comprising the steps of:
preparing a surface of a substrate, and of
depositing a transparent inorganic protective coating on said surface by a vacuum deposition method;
wherein said deposition step is carried out from at least one source of at least one material chosen so that the protective coating has a refractive index substantially equal to that of the substrate in the visible range of the light spectrum, said step also being carried out so that the protective coating has a thickness comprised between 300 nm and 5 μm.

10. The manufacturing method as claimed in claim 9, wherein the step of depositing a protective coating is carried out by cathodic sputtering method.

11. The manufacturing method according to claim 9, wherein the protective coating is deposited from at least two sources of different materials, said materials being chosen so that, during the deposition step, they each form a compound having, in the visible range of the light spectrum, respectively a refractive index greater than that of the substrate and a refractive index less than that of the substrate, the sputtering power of each of the sources being controlled so that the proportions of each compound in the protective coating are such that said coating has a refractive index substantially identical to that of the substrate.

12. The manufacturing method according to claim 9, wherein the protective coating is deposited from at least one source of a mixture of materials, said materials being chosen so that, during the deposition step, they each form a compound having, in the visible range of the light spectrum, respectively a refractive index greater than that of the substrate and a refractive index lower than that of the substrate, said source being prepared so as to include predefined proportions of said materials so that the protective coating has, at the end of the deposition step, a refractive index substantially identical to that of the substrate.

13. The manufacturing method according to claim 11, wherein the materials chosen are Al and Ti, the deposition step being carried out using O₂ as the reactive gas so that, at the end of the deposition step, the protective coating comprises a mixture of TiO₂ and Al₂O₃ so as to form a compound of the type TiₓAl_{y}O_{z}.

14. The manufacturing method according to claim 9, wherein the protective coating is deposited from at least one source of a single material chosen so that, during the deposition step, it forms several compounds by reacting with several reactive gases present, said compounds having, in the visible range of the light spectrum, respectively a refractive index greater than that of the substrate and a refractive index lower than that of the substrate, the reactive gases being present in predefined proportions so that, at the end of the deposition step, the protective coating has a refractive index substantially identical to that of the substrate.

15. The manufacturing method according to claim 14, wherein the deposition step is carried out from a source made of Si and using O₂ and N₂ as reactive gases so that, at the end of the deposition step, the protective coating comprises a mixture of SiO₂ and Si₃N₄ so as to form a compound of the type SiₓO_{y}N_{z}.
